(19) United States
(12) Patent Application Publication
(10) Pub. No.: US 2024/0049433 A1
(43) Pub. Date: Feb. 8, 2024

(54) HEAT-DISSIPATING NET STRUCTURE

(71) Applicant: MING-CHENG CHEN, TAICHUNG CITY (TW)

(72) Inventor: MING-CHENG CHEN, TAICHUNG CITY (TW)

(21) Appl. No.: 17/880,118

(22) Filed: Aug. 3, 2022

(51) Int. Cl. H05K 7/20

(52) U.S. Cl. CPC H05K 7/20509; H05K 7/20409

(57) ABSTRACT

A heat-dissipating net structure disposed in a vapor chamber unit includes latitudinal strand units and longitudinal strand units crossing each other. Each latitudinal strand unit has a single latitudinal strand extending in a first direction. Each longitudinal strand unit has at least two longitudinal strands extending in a second direction different from the first direction, with the longitudinal strands passing over and under the latitudinal strand units and twisting densely in the second direction to form a plurality of crossing points between the longitudinal strands because of the twisting arrangement. The twisting arrangement of the longitudinal strands prevents unnecessary spaces formed between any two adjacent longitudinal strand units, improves the capillary phenomenon of working fluid within the vapor chamber unit, and facilitates the phase transition of the working fluid, thereby attaining the effect of dissipating heat quickly.

### BACKGROUND OF THE INVENTION

### 1. Field of the Invention

This invention relates to a heat dissipation structure and relates particularly to a heat-dissipating net structure.

### 2. Description of the Related Art

Owing to the technological progress and lifestyle changes, electronic products are developed to have light weight, minimized volume, multi-function, and high working efficiency. The entire design of the electronic products also becomes complicated. The heat generation of the electronic products also increases accordingly caused by the improved working efficiency and more functions. If the heat generated when the electronic products work cannot be dissipated timely, the electronic products will be overheated easily, and that may affect the working efficiency of the electronic products and may even damage the electronic products. Thus, the heat-dissipating net structure 1 is commonly adapted to dissipate the heat of the electronic products and is one of the indispensable heat treatment components.

Referring to FIGS. 1, 1A and 2A, the conventional heat-dissipating net structure 1 is installed in a vapor chamber unit 2. The vapor chamber unit 2 includes two casings 21 engaged together and an accommodation room 22 defined between the casings 21. The accommodation room 22 is filled with working fluid 23. The heat-dissipating net structure 1 is accommodated in the accommodation room 22 and includes a plurality of latitudinal strand units 11 extending in a first direction A1 and spaced apart from each other and a plurality of longitudinal strand units 12 extending in a second direction A2 and spaced apart from each other. The latitudinal strand units 11 and the longitudinal strand units 12 cross together to form a plurality of holes 13 therebetween. Each latitudinal strand unit 11 and each longitudinal strand unit 12 is respectively settled in a single line arrangement. In other words, each latitudinal strand unit 11 has one latitudinal strand 111. Each longitudinal strand unit 12 has one longitudinal strand 121. The first direction A1 is different from the second direction A2. When one of the casings 21 is in contact with an electronic product (not shown) which generates heat, the working fluid 23 filled in the vapor chamber unit 2 is adapted to execute the heat exchange operation. The working fluid 23 is then vaporized and flows from a high temperature area to a low temperature area, and then is condensed and flows back though the heat-dissipating net structure 1 to thereby complete the phase transition and dissipate the heat outward. The continuous phase transition of the working fluid 23 facilitates the heat dissipation of the electronic product.

However, the latitudinal strand units 11 and the longitudinal strand units 12 are welded together to cause a plurality of joints 14. Each joint 14 is a point where one of the latitudinal strand units 11 and one of the longitudinal strand units 12 overlap. Referring to FIG. 2A, the vaporized working fluid 23 will flow upward along the longitudinal strand units 12 and immediately move to the left side and the right side of the heat-dissipating net structure 1 when meeting the joints 14. Referring to FIG. 2B, the vaporized working fluid 23 will continue flowing upward only after the latitudinal strand units 11 and the longitudinal strand units 12 that are located at the level same as a flowing height of the working fluid 23 are filled. Referring to FIGS. 2C and 2D, the vaporized working fluid 23 flows and moves leftward and rightward accordingly when meeting the joints 14. The vaporized working fluid 23 then continues moving upward after the latitudinal strand units 11 and the longitudinal strand units 12 that are located at the same level are filled. Hence, the working fluid 23 cannot synchronously flow upward, leftward and rightward through the heat-dissipating net structure 1. The latitudinal strand units 11 and the longitudinal strand units 12 that are located at the level which is same as the flowing height of the working fluid 23 should be filled simultaneously before the working fluid 23 keeps flowing upward and filling the entire heat-dissipating net structure 1, and that results in low flowing speed, unfavorable capillary phenomenon, and poor effect of dissipating heat. If each longitudinal strand unit 12 is adapted to have at least two longitudinal strands 121 in order to improve the capillary phenomenon of the working fluid 23, the longitudinal strands 121 of each longitudinal strand unit 12 will separate easily because the longitudinal strands 121 are not joined properly, and that will cause unnecessary spaces formed between any two adjacent longitudinal strand units 12. Further, the working fluid 23 may accumulate in the unnecessary spaces easily. The flowing resistance will also increase. These problems need to be improved.

### SUMMARY OF THE INVENTION

The object of this invention is to provide a heat-dissipating net structure capable of restricting longitudinal strands of each longitudinal strand unit effectively, preventing unnecessary spaces formed between any two adjacent longitudinal strand units, improving the capillary phenomenon and the phase transition of working fluid, and facilitating quick heat dissipation.

The heat-dissipating net structure includes a plurality of latitudinal strand units spaced apart from each other and a plurality of longitudinal strand units spaced apart from each other. The latitudinal strand units and the longitudinal strand units overlap each other. Each latitudinal strand unit has a single latitudinal strand extending in a first direction. Each longitudinal strand unit has at least two longitudinal strands passing over and under the latitudinal strand units in a second direction which is different from the first direction. The longitudinal strands are joined together in a dense twisting arrangement to form a plurality of crossing points between the longitudinal strands. The crossing points are spaced from each other. Hence, the dense twisting arrangement of the longitudinal strands attains a tight engagement, prevents unnecessary spaces formed between any two adjacent longitudinal strand units, improves the capillary phenomenon of working fluid within a vapor chamber unit in which the heat-dissipating net structure is disposed, and facilitates the phase transition of the working fluid, thereby facilitating the effect of quick heat dissipation.

Preferably, the heat-dissipating net structure is adapted to be disposed in a vapor chamber unit. The vapor chamber unit includes two casings, an accommodation room defined between the two casings and adapted to accommodate the heat-dissipating net structure. The accommodation room is filled with working fluid.

Preferably, the working fluid flows in a flowing direction after being vaporized in the vapor chamber unit. The flowing direction follows the second direction.

Preferably, the latitudinal strand units and the longitudinal strand units are made of metal material.

### BRIEF DESCRIPTION OF THE DRAWINGS

FIG. 1 is a schematic view showing a conventional heat-dissipating net structure adapted to be disposed in a vapor chamber unit;

FIG. 1A is an enlarged view of the encircled portion 1A indicated in FIG. 1;

FIGS. 2A, 2B, 2C and 2D are schematic views showing a flowing action of the vaporized working fluid;

FIG. 3 is a schematic view showing a first preferred embodiment of this invention adapted to be disposed in a vapor chamber unit;

FIG. 3A is an enlarged view of the encircled portion 3A indicated in FIG. 3;

FIG. 4 is a schematic view showing a flowing action of the vaporized working fluid; and

FIG. 5 is a cross-sectional view showing the first preferred embodiment as seen along the line A-A of FIG. 3A.

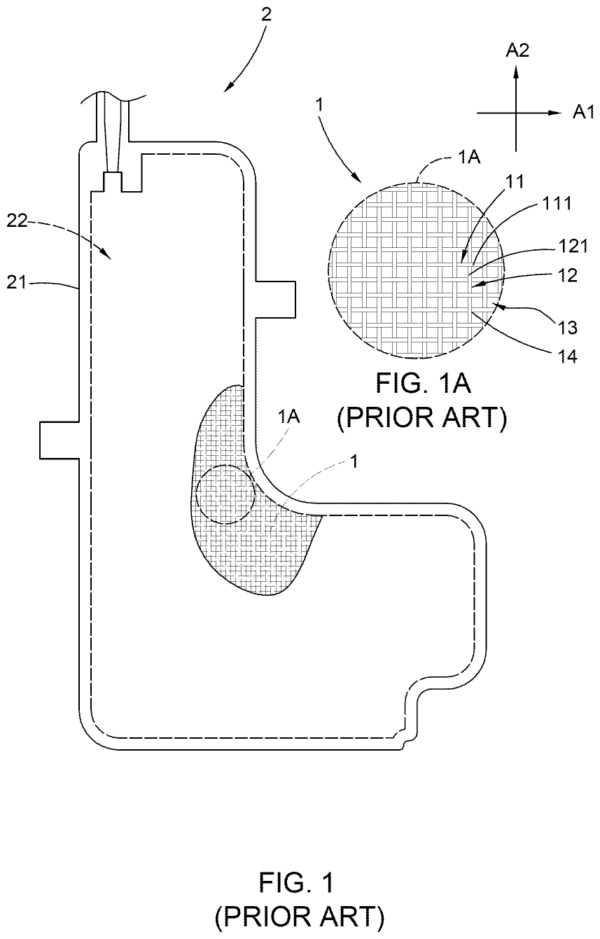

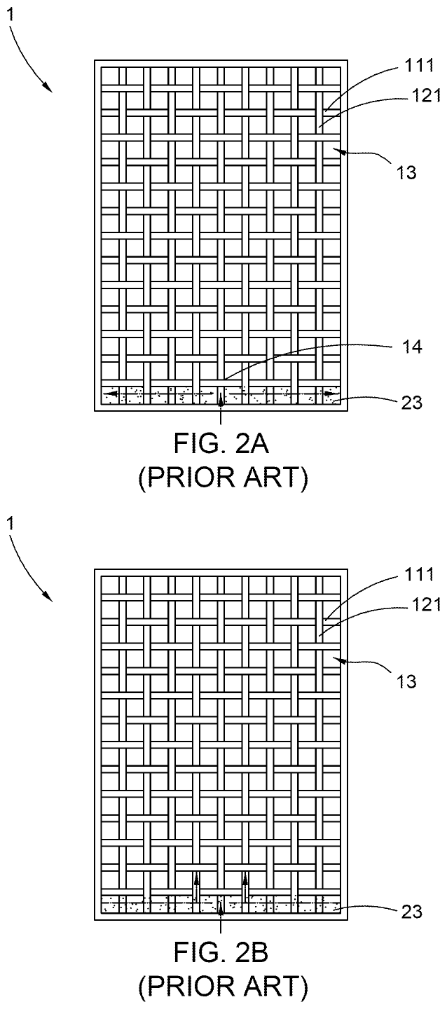

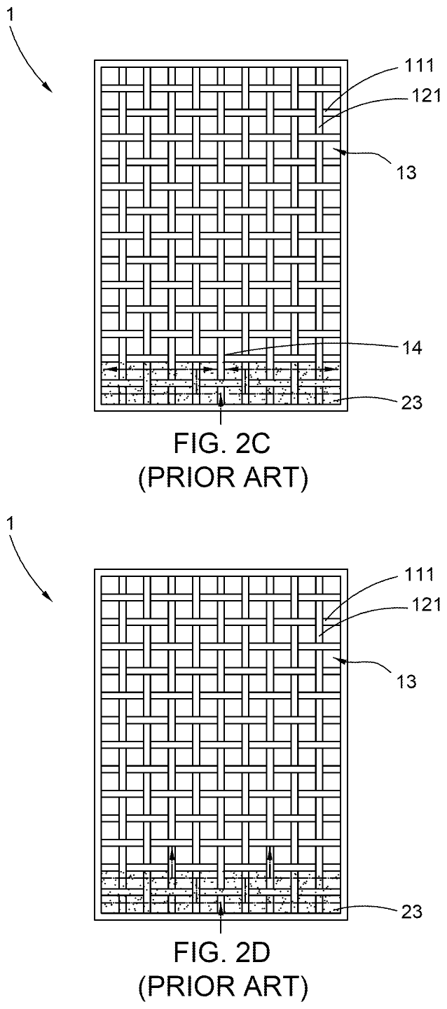

### DETAILED DESCRIPTION OF THE PREFERRED EMBODIMENTS

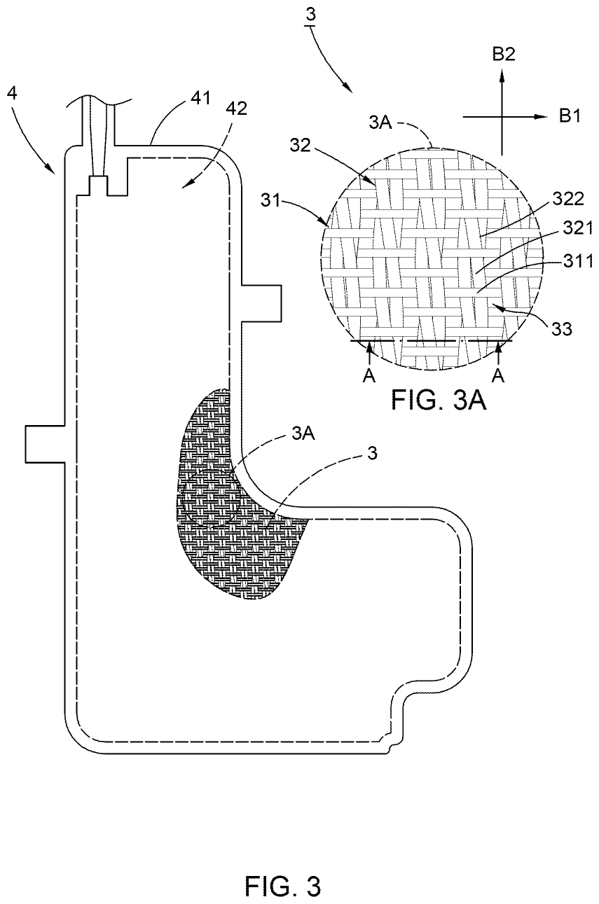

Referring to FIG. 3 and FIG. 3A, a first preferred embodiment of a heat-dissipating net structure 3 is disclosed. In this preferred embodiment, the heat-dissipating net structure 3 is adapted to be disposed in a vapor chamber unit 4. The vapor chamber unit 4 includes two casings 41 engaged together and an accommodation room 42 defined between the casings 41 and adapted to accommodate the heat-dissipating net structure 3. The accommodation room 42 is filled with working fluid 43 and vacuum pumped. The heat-dissipating net structure 3 includes a plurality of latitudinal strand units 31 and a plurality of longitudinal strand units 32 crossing with the latitudinal strand units 31 to form a plurality of holes 33 therebetween. The latitudinal strand units 31 are spaced apart from each other and extend in a first direction B1. The longitudinal strand units 32 are spaced apart from each other and extend in a second direction B2 which is different from the first direction B1. Here takes an example that the first direction B1 is parallel with the horizontal plane. The second direction B2 is perpendicular to the first direction B1. After the working fluid 43 is vaporized in the vapor chamber unit 4, the working fluid 43 flows in a flowing direction following the second direction B2. After the working fluid 43 is condensed, the working fluid 43 flows in another flowing direction opposite to the second direction B2.

Each latitudinal strand unit 31 has a single latitudinal strand 311 extending in the first direction B1. Each longitudinal strand unit 32 has at least two longitudinal strands 321. The longitudinal strands 321 of each longitudinal strand unit 32 pass over and under the latitudinal strand units 31 while extending in the second direction B2. The longitudinal strands 321 are integrated together in a twisting mode to form a plurality of crossing points 322 between the longitudinal strands 321 whereby the longitudinal strands 321 are joined tightly. The crossing points 322 are spaced from each other. The number of the longitudinal strands 321 of each longitudinal strand unit 32 can be varied according to needs. Here takes an example that each longitudinal strand unit 32 has three longitudinal strands 321. The latitudinal strand units 31 and the longitudinal strand units 32 are made of metal material with high thermal conductivity such as copper, aluminum, nickel, stainless steel and so on.

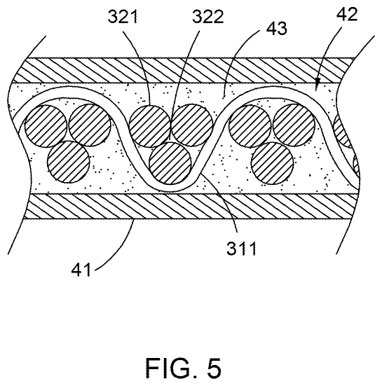

Referring to FIGS. 3 and 5, when using the vapor chamber unit 4, the vapor chamber unit 4 is disposed on an electronic product (not shown) to allow one of the casings 41 of the vapor chamber unit 4 to be in close contact with the electronic product. The vapor chamber unit 4 can be installed to an area of the electronic product that generates more heat. The material of the working fluid 43 can be varied according to the operating temperature of the electronic product. When the electronic product operates and generates heat, the casing 41 which is in contact with the electronic product is heated. The working fluid 34 filled in the vapor chamber unit 4 is vaporized accordingly owing to the heat. The vaporized working fluid 34 then moves from a high temperature area to a low temperature area through the heat-dissipating net structure 3, namely the vaporized working fluid 34 flows in the flowing direction which follows the second direction B2 through the latitudinal strands 311 and the longitudinal strands 321.

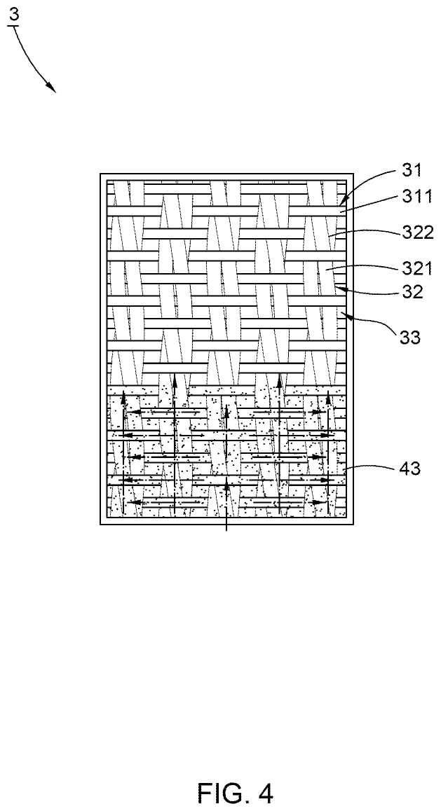

Referring to FIG. 4, during the flowing action of the vaporized working fluid 43, the working fluid 43 will synchronously flows upward along the longitudinal strands 321 of the longitudinal strand units 32 and move leftward and rightward along the latitudinal strands 311 of the latitudinal strand units 31 whereby simultaneous upward, leftward and rightward flowing actions of the working fluid 43 are attained. Thus, the working fluid 43 flows speedily thereby conducting the heat of the electronic product to the low temperature area quickly and dissipating the heat outward effectively. Because each longitudinal strand unit 32 is formed by at least two longitudinal strands 321, the capillary phenomenon of the working fluid 43 is improved effectively. The longitudinal strands 321 of each longitudinal strand unit 32 are twisted densely to form the crossing points 322. The crossing points 322 can ensure that the longitudinal strands 321 are united tightly and will not separate easily to thereby prevent unnecessary spaces formed between the longitudinal strands 321 effectively, reduce the flowing resistance of the working fluid 43, prevent the working fluid 43 from accumulating in the unnecessary spaces, and maintain proper spaces formed between any two adjacent longitudinal strand units 32. The vaporized working fluid 43 is then condensed into liquid after releasing the heat and flows downward along the latitudinal strands 311 and the longitudinal strands 321. Hence, the working fluid 43 flows smoothly and quickly to execute the phase transition thereby attaining the effect of dissipating heat quickly, maintaining the smooth operation of the electronic product, and ensuring that the electronic product will not be damaged owing to overheating.

To sum up, the heat-dissipating net structure of this invention takes advantages that each longitudinal strand unit has at least two longitudinal strands crossing with the latitudinal strand units and twisting densely to form the crossing points thereby preventing unnecessary spaces formed between any two adjacent longitudinal strand units, improving the capillary phenomenon of the working fluid within the vapor chamber unit, and facilitating the phase transition of the working fluid whereby the effect of quick heat dissipation is attained.

While the embodiments of this invention are shown and described, it is understood that further variations and modifications may be made without departing from the scope of this invention.

What is claimed is:

1. A heat-dissipating net structure comprising:
a plurality of latitudinal strand units extending in a first direction and spaced apart from each other; and
a plurality of longitudinal strand units spaced apart from each other and extending in a second direction different from said first direction, with said plurality of latitudinal strand units and said plurality of longitudinal strand units crossing each other;
wherein each of said plurality of latitudinal strand units includes a single latitudinal strand extending in said first direction, each of said plurality of longitudinal strand units including at least two longitudinal strands, said at least two longitudinal strands passing over and under said plurality of latitudinal strand units in said second direction, said at least two longitudinal strands being joined together in a twisting mode to form a plurality of crossing points between said at least two longitudinal strands, said plurality of crossing points being spaced from each other.

2. The heat-dissipating net structure according to claim 1, wherein said heat-dissipating net structure is adapted to be disposed in a vapor chamber unit, said vapor chamber unit including two casings and an accommodation room defined between said two casings and adapted to accommodate said heat-dissipating net structure, with said accommodation room filled with working fluid.

3. The heat-dissipating net structure according to claim 2, wherein said working fluid flows in a flowing direction after being vaporized in said vapor chamber unit, with said flowing direction following said second direction.

4. The heat-dissipating net structure according to claim 1, wherein said plurality of latitudinal strand units and said plurality of longitudinal strand units are made of metal material.
